(19) United States
(12) Patent Application Publication
(10) Pub. No.: US 2026/0276402 A1
(43) Pub. Date: Sep. 17, 2026

(54) WALKING TRAJECTORY ANALYSIS APPARATUS, MOVEMENT TRAJECTORY ANALYSIS APPARATUS, WALKING TRAJECTORY ANALYSIS METHOD, AND NON-TRANSITORY COMPUTER READABLE STORAGE MEDIUM STORING COMPUTER PROGRAM

(71) Applicant: SUMITOMO ELECTRIC INDUSTRIES, LTD., Osaka-shi, Osaka (JP)

(72) Inventor: Hiroki KATO, Osaka-shi (JP)

(73) Assignee: SUMITOMO ELECTRIC INDUSTRIES, LTD., Osaka-shi, Osaka (JP)

(21) Appl. No.: 19/156,695

(22) PCT Filed: Jan. 15, 2024
(86) PCT No.: PCT/JP2024/000856

§ 371 Date: Aug. 14, 2025

(30) Foreign Application Priority Data
Feb. 24, 2023 (JP) 2023-027328

(51) Int. Cl. G01C 21/00; G06F 30/20

(52) U.S. Cl. CPC G01C 21/3807; G06F 30/20

(57) ABSTRACT

A walking trajectory analysis apparatus analyzes a walking trajectory of a pedestrian. The walking trajectory analysis apparatus includes a storage unit configured to store, as internal trajectories, time-series data of a pedestrian position based on detection data from a detector with a detection area including a crosswalk; and a control unit configured to calculate an external trajectory based on an internal trajectory determined to be jaywalking among the internal trajectories stored in the storage unit, the external trajectory being the walking trajectory outside the detection area, the jaywalking involving crossing a roadway area excluding the crosswalk.

### TECHNICAL FIELD

The present disclosure relates to a walking trajectory analysis apparatus, a movement trajectory analysis apparatus, an analysis method, and a computer program. This application claims priority based on Japanese Patent Application No. 2023-27328 filed on Feb. 24, 2023, the entire contents of which are incorporated herein by reference.

### BACKGROUND ART

A technique is known in which a moving object around an intersection is sensed and caution information indicating a position at which crossing of a pedestrian occurs is generated. For example, in Patent Literature 1, when there is a position at which crossing occurs through a position different from a position at which a crosswalk is formed, caution information about such a position is generated. Further, the driver of the vehicle is notified of information on a pedestrian who crosses a roadway area excluding a crosswalk (hereinafter referred to as “jaywalking ”).

### CITATION LIST

### Patent Literature

Patent literature 1: Japanese Unexamined Patent Application Publication No. 2021-026560

### SUMMARY OF INVENTION

A walking trajectory analysis apparatus according to one aspect of the present disclosure is an apparatus for analyzing a walking trajectory of a pedestrian, the walking trajectory analysis apparatus includes a storage unit configured to store, as internal trajectories, time-series data of a pedestrian position based on detection data from a detector with a detection area including a crosswalk, and a control unit configured to calculate an external trajectory based on an internal trajectory determined to be jaywalking among the internal trajectories stored in the storage unit, the external trajectory being the walking trajectory outside the detection area, the jaywalking involving crossing a roadway area excluding the crosswalk.

A walking trajectory analysis method according to one aspect of the present disclosure is a method for analyzing a walking trajectory of a pedestrian by a computer.

The walking trajectory analysis method includes storing, as internal trajectories, time-series data of a pedestrian position based on detection data from a detector with a detection area including a crosswalk, and calculating an external trajectory based on an internal trajectory determined to be jaywalking among the stored internal trajectories, the external trajectory being the walking trajectory outside the detection area, the jaywalking involving crossing a roadway area excluding the crosswalk.

A computer program according to one aspect of the present disclosure is a computer program for causing a computer to function as an apparatus for analyzing a walking trajectory of a pedestrian. The computer program causing the computer to function as a storage unit configured to store, as internal trajectories, time-series data of a pedestrian position based on detection data from a detector with a detection area including a crosswalk, and a control unit configured to calculate an external trajectory based on an internal trajectory determined to be jaywalking among the internal trajectories stored in the storage unit, the external trajectory being the walking trajectory outside the detection area, the jaywalking involving crossing a roadway area excluding the crosswalk.

### BRIEF DESCRIPTION OF THE DRAWINGS

FIG. 1 is a system configuration diagram showing an example of a safe driving assistance system.

FIG. 2 is a flowchart showing an example of a walking trajectory analysis process.

FIG. 3 is an explanatory diagram showing an example of an algorithm of motion estimation.

FIG. 4 is a road plan view showing an example of image output of a walking trajectory.

### DETAILED DESCRIPTION

### Problem to be Solved by the Disclosure

The technique described in Patent Literature 1 only specifies the position of the pedestrian from the image captured by the in-vehicle camera, and does not assume the behavior of the jaywalking starting from the outside of the angle of view of the in-vehicle camera. Further, in Patent Literature 1, only the caution information is generated and notified, and it is not assumed that the intersection environment is improved when there is a problem in the infrastructure environment of the intersection, such as the position of the guardrail being inappropriate. In view of the above problems, an object of the present disclosure is to appropriately analyze a walking trajectory determined as a jaywalking.

### Advantageous Effects of Present Disclosure

According to the present disclosure, a walking trajectory determined as a jaywalking can be appropriately analyzed.

### Overview of Embodiments of the Present Disclosure

The following is a summary of the embodiments of the present disclosure. (1) A walking trajectory analysis apparatus according to one aspect of the present embodiment is an apparatus for analyzing a walking trajectory of a pedestrian, the walking trajectory analysis apparatus includes a storage unit configured to store, as internal trajectories, time-series data of a pedestrian position based on detection data from a detector with a detection area including a crosswalk, and a control unit configured to calculate an external trajectory based on an internal trajectory determined to be jaywalking among the internal trajectories stored in the storage unit, the external trajectory being the walking trajectory outside the detection area, the jaywalking involving crossing a roadway area excluding the crosswalk.

According to the analysis apparatus of the embodiment, the control unit calculates the external trajectory which is the walking trajectory outside the detection area based on the internal trajectory determined as the jaywalking which is the crossing of the roadway area excluding the crosswalk, and thus, even when the jaywalking occurs from the outside of the detection area, the walking trajectory of the jaywalking is calculated. Thus, it is possible to appropriately analyze the walking trajectory determined as the jaywalking.

(2) In the above (1), the control unit may be capable of executing image output to draw the walking trajectory on a road map including the crosswalk, and a target to be drawn through the image output may include a first trajectory, the first trajectory being the walking trajectory including the external trajectory. In this way, the user can visually recognize the shape of the first trajectory including the jaywalking.

(3) In the above (2), the target to be drawn through the image output may further include a second trajectory, the second trajectory being the walking trajectory not including the external trajectory, and the first trajectory and the second trajectory may be displayed in different manners that are distinguishable by a user. In this way, the user can easily distinguish the shape of the first trajectory including the jaywalking and the shape of the second trajectory not including the jaywalking.

(4) In the above (2) or (3), the control unit may be configured to determine a jaywalking-triggering point at which the pedestrian who performs the jaywalking starts to enter a roadway, and the target to be drawn through the image output may further include the jaywalking-triggering point. In this way, the user can easily visually recognize the position of the jaywalking-triggering point, which is the starting point of the jaywalking.

(5) In the above (4), the target to be drawn through the image output may further include an installation point of a structure configured to control the jaywalking, the installation point being identified based on the jaywalking-triggering point. In this way, the user can easily visually recognize the position of the installation points for structures that control the jaywalking.

(6) In any one of the above (1) to (5), the control unit may be configured to determine the jaywalking, based on a time during which the pedestrian is continuously present in the roadway area excluding the crosswalk. In this way, the control unit can objectively and easily determine whether or not the jaywalking is present based on the internal trajectory.

(7) A walking trajectory analysis method according to one aspect of the embodiment is a method for analyzing a walking trajectory of a pedestrian by a computer. The walking trajectory analysis method includes storing, as internal trajectories, time-series data of a pedestrian position based on detection data from a detector with a detection area including a crosswalk, and calculating an external trajectory based on an internal trajectory determined to be jaywalking among the stored internal trajectories, the external trajectory being the walking trajectory outside the detection area, the jaywalking involving crossing a roadway area excluding the crosswalk. The method is an analysis method executed by the analysis apparatus of (1) to (6) described above. Thus, the analysis method of the embodiment has the same operational effects as the analysis apparatus of the above (1) to (6).

(8) A computer program according to one aspect of the embodiment is a computer program for causing a computer to function as an apparatus for analyzing a walking trajectory of a pedestrian. The computer program causing the computer to function as a storage unit configured to store, as internal trajectories, time-series data of a pedestrian position based on detection data from a detector with a detection area including a crosswalk, and a control unit configured to calculate an external trajectory based on an internal trajectory determined to be jaywalking among the internal trajectories stored in the storage unit, the external trajectory being the walking trajectory outside the detection area, the jaywalking involving crossing a roadway area excluding the crosswalk. The computer program is a computer program that causes a computer to function as the analysis apparatus of (1) to (6) described above. Thus, the computer program of the embodiment has the same operational effects as the analysis apparatus of the above (1) to (6).

(9) A movement trajectory analysis apparatus according to one aspect of the embodiment is a device for analyzing a movement trajectory of a moving object. The movement trajectory analysis apparatus includes a storage unit configured to store, as internal trajectories, time-series data of a moving-object position based on detection data from a detector with a detection area including a crosswalk, and a control unit configured to calculate an external trajectory based on an internal trajectory determined to be jaywalking among the internal trajectories stored in the storage unit, the external trajectory being the movement trajectory outside the detection area, the jaywalking involving crossing a roadway area excluding the crosswalk.

According to the apparatus of the embodiment, the control unit calculates the external trajectory which is the movement trajectory outside the detection area based on the internal trajectory determined as the jaywalking which is the crossing of the roadway area excluding the crosswalk, and thus, even when the jaywalking occurs from the outside of the detection area, the movement trajectory of the jaywalking is calculated. Thus, it is possible to appropriately analyze the movement trajectory determined as the jaywalking.

The embodiments of the present disclosure may be implemented by an apparatus, a system, a method, an integrated circuit, a computer program, a non-transitory computer-readable recording medium, or any combination thereof. The recording medium may be volatile or nonvolatile. The apparatus may be composed of a plurality of individual devices. In the case of being configured by a plurality of individual devices, the devices may be arranged in one housing or may be arranged separately in two or more housings separated from each other.

### Details of Embodiment of Present Disclosure

The details of the embodiments of the present disclosure are set forth in the accompanying drawings and the description below. It is noted that, at least some of the embodiments described below may be combined as desired.

### Definition of Terms

In describing the embodiment in detail, terms are first defined. “Sidewalk”: A sidewalk in this specification refers to a portion of a road that is intended to be dedicated exclusively to the passage of pedestrians.

“Roadway”: A roadway in this specification refers to a portion of a road that is intended to be dedicated exclusively to the passage of vehicles.

“Detector”: Refers to a sensor capable of detecting an object such as a pedestrian in a non-contact manner. The sensing principle of the detector is not particularly limited, and a millimeter-wave radar, a digital camera capable of capturing a moving image, or the like can be adopted as the detector.

“Detection area”: Refers to a spatial range in which the detector can detect an object, that is, a spatial range in which an object can be detected as a detection target.

“Detection data”: Refers to the data of a predetermined physical quantity output by the detector to the outside. In the embodiment, the detection data is original data necessary for calculating time-series data of the pedestrian position. The detection data of the millimeter wave radar includes, for example, a distance of the target object from an installation position (reference point) of the detector, a speed of the target object, and reception power, and the like. The detection data of the digital camera is, for example, pixel data captured at each predetermined frame rate.

### Overall Configuration of System

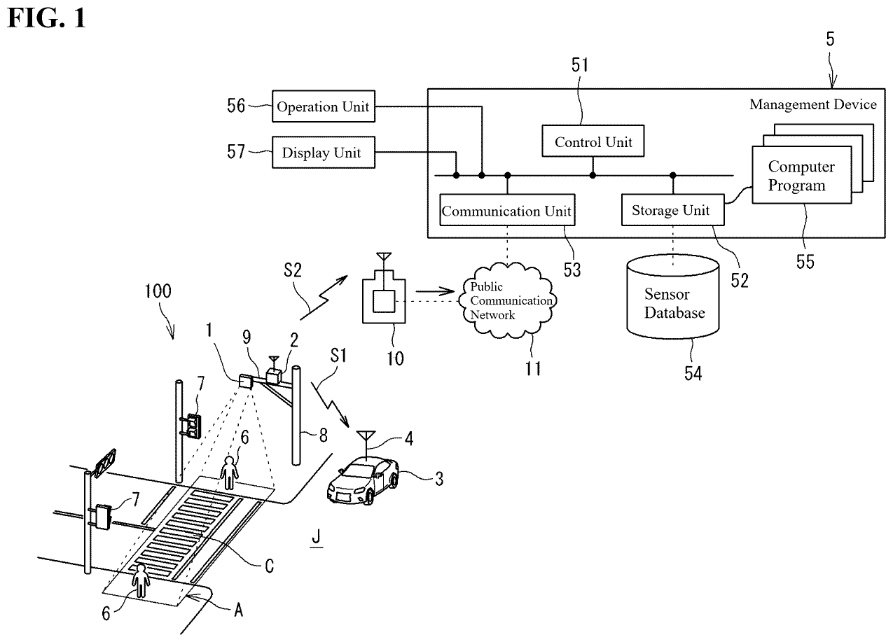

FIG. 1 is a system configuration diagram showing an example of a safe driving assistance system 100. As shown in FIG. 1, a safe driving assistance system (hereinafter also referred to as “assistance system”) 100 includes a detector 1 for detecting a pedestrian 6, a roadside communication device 2 connected to the detector 1, an in-vehicle communication device 4 included in a vehicle 3, a management device 5, and the like.

The safe driving assistance system 100 of the embodiment provides a service for calling attention of the driver of the vehicle 3 that turns right or left at an intersection J by the roadside communication device 2 transmitting a presence information S1 of the pedestrian 6 in a crosswalk C detected by the detector 1 to the in-vehicle communication device 4. A pedestrian light 7 for displaying the presence or absence of the right of way of the pedestrian 6 is installed at the intersection J. A pole 8 for a sensor is installed at the intersection J. The detector 1 and the roadside communication device 2 are installed on a pole arm 9 attached to the pole 8.

The detector 1 is a kind of “roadside sensor” specialized for detection of the pedestrian 6, and is configured by a millimeter wave radar such as a 24 GHz band, for example. The detector 1 is also referred to as a pedestrian sensor. The roadside sensor for detecting the presence of the pedestrian 6 may be an image type sensor such as a digital camera. However, from the viewpoint of being resistant to environmental changes such as changes in sunshine conditions and weather conditions, the millimeter wave radar has higher detection accuracy than the image type sensor under bad weather. The detector 1 of the embodiment is a millimeter-wave radar.

The number of detectors 1 installed for one crosswalk C is not limited to one. That is, two or more millimeter-wave radars may be installed for one crosswalk C so that a detection area A covers one crosswalk C in an overlapping manner. The roadside communication device 2 is, for example, an intelligent transport systems (ITS) wireless device or a cellular wireless device corresponding to a cellular V2X (Vehicle to X). However, the roadside communication device 2 may have both functions of the ITS wireless device and the cellular wireless device.

The detector 1 is connected to the roadside communication device 2 via an I/O communication line (not shown) of a predetermined standard. The detection data output by the detector 1 includes, for example, the distance of the target object from the installation position (reference point) of the detector 1, the speed of the target object, the reception power, and the like. The roadside communication device 2 includes a processing unit that determines whether or not the pedestrian 6 is included in the target object. This determination is performed, for example, based on whether or not the speed of the target object included in the detection data, the traveling direction of the target object obtained from the speed, and the like conform to a predetermined operation model.

The processing unit of the roadside communication device 2 generates and broadcasts the presence information S1 of the pedestrian 6 when it detects the pedestrian 6 as the target object. Specifically, when the roadside communication device 2 is an ITS wireless device, the presence information S1 of the pedestrian 6 is directly wirelessly transmitted to the in-vehicle communication device 4 compatible with the ITS. When the roadside communication device 2 is a cellular wireless device, the presence information S1 of the pedestrian 6 is transmitted to a wireless base station 10. In this case, the wireless base station 10 transmits the received presence information S1 to the in-vehicle communication device 4 having a cellular communication function via an edge server (not illustrated) or the like.

The processing unit of the roadside communication device 2 also has a function of transferring the detection data input from the detector 1 as raw data. Specifically, the roadside communication device 2 includes a buffer that accumulates a predetermined amount of detection data. The processing unit of the roadside communication device 2 generates a communication frame S2 addressed to the management device 5 including the detection data extracted from the buffer in the payload, and transmits the generated communication frame S2 to the wireless base station 10.

### Hardware Configuration of Management Device

As shown in FIG. 1, the management device 5 is a computer connected to a public communication network 11, and includes a control unit 51, a storage unit 52, and a communication unit 53, which are accommodated in a housing, and a sensor database 54 constructed in the storage unit 52. The user of the management device 5 is, for example, an operation manager of the traffic control system for performing signal control of the intersection J.

The sensor database 54 is electronic data constructed in a predetermined data array in the storage unit 52. However, a part or all of the sensor database 54 may be constructed in an external storage device (not shown) connected to the housing of the management device 5. An operation unit 56 and a display unit 57 are connected to the housing of the management device 5. Although a desktop computer is illustrated as an example of the management device 5 in FIG. 1, the management device 5 may be a mobile computer such as a notebook computer or a tablet computer.

The control unit 51 is an arithmetic processing unit including a central processing unit (CPU), a random access memory (RAM), and the like. The control unit 51 may include an integrated circuit such as a field-programmable gate array (FPGA). The control unit 51 reads a computer program 55 stored in the storage unit 52 into a main memory (RAM) and executes various information processing. The information processing includes processing of analyzing a walking trajectory of the pedestrian 6 crossing the roadway based on the detection data of the detector 1.

Thus, the management device 5 of the embodiment has a function as a walking trajectory analysis apparatus focusing on the pedestrian 6 crossing the roadway as an analysis target. The storage unit 52 is an auxiliary storage device including a nonvolatile memory such as a hard disk drive (HDD) and a solid state drive (SSD). The storage unit 52 may include a flash ROM (Read Only Memory), a USB (Universal Serial Bus) memory, an SD card, or the like.

The communication unit 53 is a communication interface connected to the public communication network 11 in accordance with a predetermined communication standard. Thus, the communication unit 53 can receive the communication frame S2 including the detection data of the detector 1 from the wireless base station 10. When the communication unit 53 receives the communication frame S2, the communication unit 53 transfers the received communication frame S2 to the control unit 51. The control unit 51 extracts the detection data from the communication frame S2 transferred from the communication unit 53, and stores the extracted detection data in the sensor database 54.

In this way, the detection data sensed by the detector 1 installed in the intersection J is accumulated in the sensor database 54 of the management device 5. Although only one intersection J is illustrated in the example of FIG. 1, the detection data of the detector 1 installed in each of the plurality of intersections J may be accumulated in the sensor database 54 by being classified for each intersection J.

The operation unit 56 is an input device such as a keyboard and a pointing device. The user of the management device 5 can transmit a predetermined instruction to the control unit 51 of the management device 5 by inputting a command to the operation unit 56 or inputting an operation such as clicking. The display unit 57 is a display device such as a liquid crystal monitor or an organic EL (Electro Luminescence) panel. The display unit 57 can display a graphical user interface (GUI) screen, or the like for receiving an operation input to the operation unit 56.

### Walking Trajectory Analysis Process

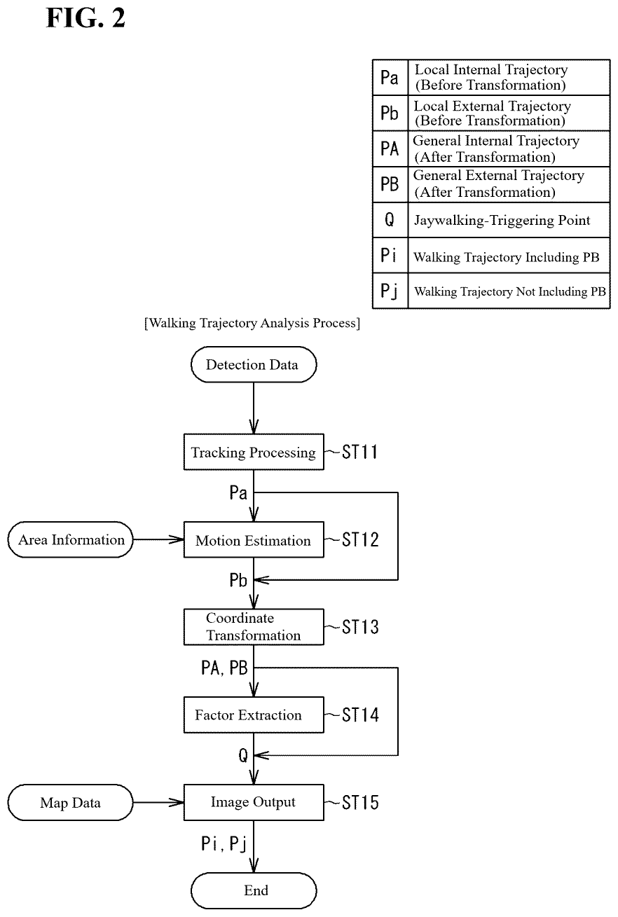

FIG. 2 is a flowchart showing an example of the walking trajectory analysis process executed by the control unit 51 of the management device 5. As shown in FIG. 2, the walking trajectory analysis process includes tracking processing (step ST11), motion estimation (step ST12), coordinate transformation (step ST13), factor extraction (step ST14), and image output (step ST15). The meaning of the parameters in FIG. 2 will be described below, and then the contents of each process will be described.

Pa: Refers to the walking trajectory of the pedestrian 6 that exists inside the detection area A, defined by the local coordinate system. Hereinafter it is referred to as a “local internal trajectory Pa”.

Pb: Refers to the walking trajectory of the pedestrian 6 that exists outside the detection area A, defined by the local coordinate system. Hereinafter it is referred to as a “local external trajectory Pb”.

As described above, the detection area A is a spatial range in which the detector 1 can detect an object. For example, in the case of the detector 1 including a millimeter-wave radar, the range means a range in which a radio wave having a predetermined reception power or more for identifying an object can be received. The local coordinate system is a local coordinate system applied to the detector 1, such as plane coordinates or polar coordinates with the installation position of the detector 1 as a reference point (origin), for example.

PA: Refers to the walking trajectory of the pedestrian 6 that exists inside the detection area A, defined by the general-purpose coordinate system. Hereinafter it is referred to as a “general internal trajectory PA”.

PB: Refers to the walking trajectory of the pedestrian 6 that exists outside the detection area A, defined by the general-purpose coordinate system. Hereinafter it is referred to as a “general external trajectory PB”.

The general-purpose coordinate system is a coordinate system having versatility, such as a latitude and longitude coordinate system, for example, which can easily perform processing such as superimposition with digital map data of the whole country and map matching.

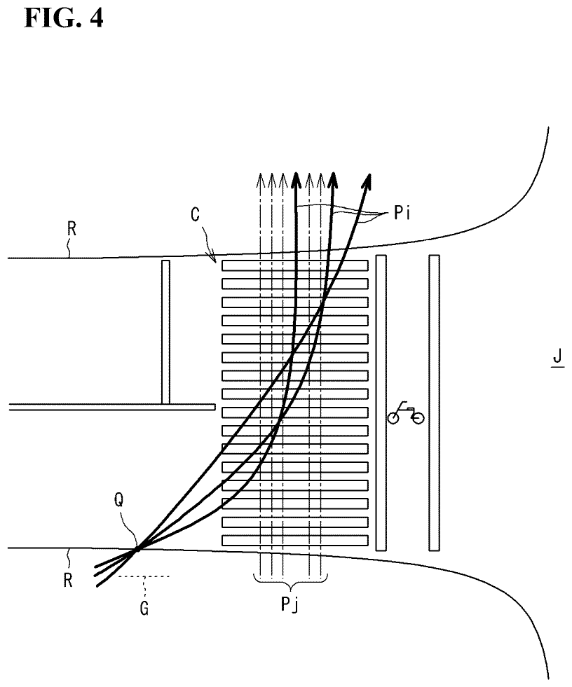

Q: Refers to a point where the pedestrian 6 making a jaywalking starts to enter the roadway (see FIG. 4). Hereinafter it is referred to as a “jaywalking-triggering point Q”.

Pi: Refers to the walking trajectory of pedestrian 6 including the general external trajectory PB, that is, the walking trajectory estimated as the jaywalking.

Hereinafter it is also referred to as a “first trajectory Pi”. It is noted that, in the case where the first trajectory Pi is output as an image, the jaywalking-triggering point Q is also displayed at the same time.

Pj: Refers to the walking trajectory of pedestrian 6 not including the general external trajectory PB, that is, a normal walking trajectory not estimated as a jaywalking.

Hereinafter it is also referred to as “second trajectory Pj”.

### Tracking Process: Step ST11

The tracking processing is processing of generating the local internal trajectory Pa of the pedestrian 6 using the detection data from the detector 1 as input information.

The tracking process is executed by, for example, arranging the positions of the target objects determined as the pedestrian 6 in time series at predetermined control intervals (for example, 0.5 seconds). Specifically, the tracking process includes the following “background difference” and “time-series process”.

The background difference is a process of removing a background by taking a difference between background data such as structure and input data. As a result, the structure near the intersection J, such as the pedestrian light 7 and the guardrail, is removed from the target object, and the target object (the pedestrian 6) moving in the detection area A is captured. The time-series processing is processing of recording, in the storage unit 52, the local internal trajectory Pa in which local coordinate values (point group) for each control cycle are arranged in time series for the same pedestrian 6 captured by the background difference. That is, the local internal trajectory Pa is time-series data of the pedestrian position based on the detection data of the detector 1.

### Motion Estimation: Step ST12

The motion estimation is a process of generating the local external trajectory Pb of the pedestrian 6 by using the area information of the detection area A and the local internal trajectory Pa as input information. The “area information” is, for example, a mathematical expression representing the extension of the detection area A, and is recorded in advance in the storage unit 52. For example, when the detection area A is a sector shape centered on the installation position of the detector 1, the area information is defined by an equation of a circle representing the outer periphery of the sector shape and linear equations of two straight lines extending in two directions from the center point of the sector shape.

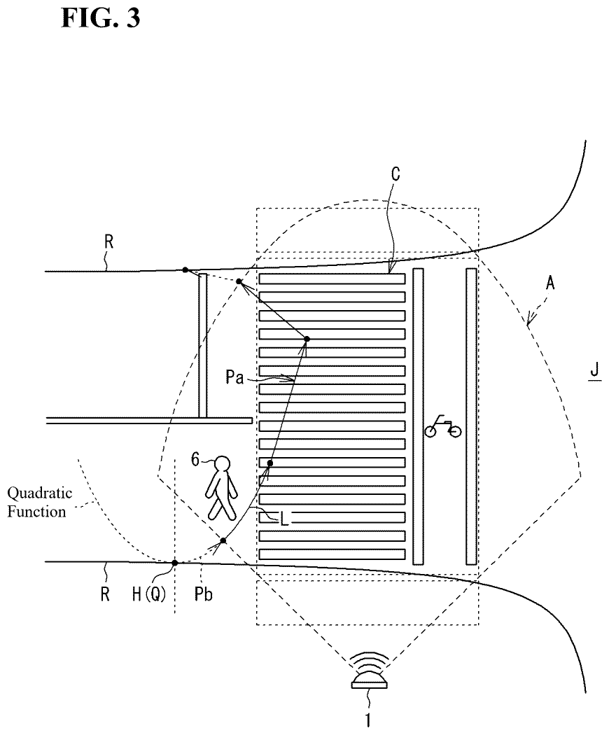

FIG. 3 is an explanatory diagram showing an example of an algorithm of motion estimation. In FIG. 3, “R” is a boundary line between a sidewalk and a roadway, and position information of a boundary line R is recorded in advance in the storage unit 52. As shown in FIG. 3, the motion estimation is performed by extracting a polynomial (for example, a second order equation) approximating an initial portion L of the local internal trajectory Pa. The initial portion L is a line segment of a predetermined length (for example, 3 m) representing an initial walking trajectory in which the pedestrian 6 starts to appear in the detection area A.

Specifically, the motion estimation is executed by the following processing. Processing a1: The local internal trajectory Pa of the pedestrian 6 determined as a jaywalking is extracted. It is noted that, the determination of the jaywalking is performed, for example, by determining whether or not the time during which the pedestrian 6 is continuously present in the roadway area excluding the crosswalk C is equal to or longer than a predetermined time (for example, three seconds).

Specifically, a first mathematical expression representing the boundary line R which is an extension of the roadway area and a second mathematical expression representing an extension of the crosswalk C are recorded in advance in the storage unit 52. Then, the control unit 51 determines the jaywalking based on the time when the pedestrian 6 is continuously present within the region surrounded by the first mathematical expression and outside the region surrounded by the second mathematical expression.

Processing a2: A plurality of quadratic functions that contact the boundary line R at a vertex H on the convex side are defined on condition that the local internal trajectory Pa determined as a jaywalking is extracted.

Processing a3: A quadratic function that is most approximate to the initial portion L of the local internal trajectory Pa of the jaywalking is selected from among the plurality of defined quadratic functions.

Processing a4: A curved portion from the vertex H of the quadratic function to the intersection of the curved path and the detection area A in the curved path along the selected quadratic function is set as the local external trajectory Pb. As will be described later, the universal coordinate value of the vertex H of the quadratic function is a kind of the above-described jaywalking-triggering point Q. Further, as a method of approximating the processing a3, an approximation formula including a polynomial other than a quadratic function may be adopted, or an approximation formula may be calculated using a least-square method in order to minimize a deviation between a trajectory near the boundary line R and the polynomial.

### Coordinate Transformation: Step ST13

The coordinate transformation is a process of generating the general internal trajectory PA and the general external trajectory PB using the local internal trajectory Pa and the local external trajectory Pb as input information. Specifically, the coordinate transformation may be performed by the following processing.

Processing b1: A general formula (for example, a determinant) for coordinate transformation is created based on the local coordinate values and the general-purpose coordinate values of the feature points (for example, the installation position of the pedestrian light 7) in the detection area A.

Processing b2: The general internal trajectory PA and the general external trajectory PB are calculated by applying the created general formulas to the local internal trajectory Pa and the local external trajectory Pb, respectively.

### Factor Extraction: Step ST14

The factor extraction is a process of determining the jaywalking-triggering point Q defined in the general-purpose coordinate systems by using the general internal trajectory PA and the general external trajectory PB as input information. In particular, the control unit 51 sets the general-purpose coordinate value of the vertex H (see FIG. 3) of the quadratic function used in the motion estimation as the jaywalking-triggering point Q.

Further, when there are the plurality of general external trajectories PB, the control unit 51 determines the jaywalking-triggering point Q (the general-purpose coordinate values of the vertex H) for each of the plurality of general external trajectories PB.

### Image Output: Step ST15

The image output is a process of generating the walking trajectories Pi and Pj for each pedestrian 6 using the general internal trajectory PA, the general external trajectory PB, and the jaywalking-triggering point Q as input information, and superimposing and drawing the generated walking trajectories Pi and Pj on map data of the intersection J displayed by the display unit 57.

The map data of the intersection J is digital map data that adopts a general-purpose coordinate system and is data including an internal structure of the intersection J. The map data may be acquired from a predetermined map distribution server or may be data generated from aerial photographs. The control unit 51 superimposes the positions of the generated walking trajectories Pi and Pj on the map data, thereby drawing the walking trajectories Pi and Pj on the map.

In the image output, the control unit 51 superimposes both the first trajectory Pi and the second trajectory Pj at the same time and displays the superimposed trajectories on the display unit 57. In this case, in order to make it easy to distinguish the difference between the two, the two trajectories Pi and Pj may be displayed in different manners (for example, colors, line thicknesses, blinking, a flowing dashed line, or the like). Further, in the image output, only the first trajectory Pi may be displayed on the display unit 57.

Furthermore, when the second trajectory Pj is displayed, the general external trajectory PB based on the estimation result by the motion estimation and the general internal trajectory PA other than the general external trajectory PB may be displayed so as to be distinguishable from each other.

### Example of Image Output of Walking Trajectory

FIG. 4 is a road plan view showing an example of image output of the walking trajectories Pi and Pj. As shown in FIG. 4, in the road plan view near the intersection J displayed on the display unit 57, the first trajectory Pi, the second trajectory Pj, and the jaywalking-triggering point Q are superimposed and drawn on the roadway portion including the crosswalk C.

In the example of FIG. 4, the first trajectory Pi including the jaywalking is drawn by a thick arrow, and the second trajectory Pj not including the jaywalking is drawn by a thin arrow of a one dot chain line. Thus, the user who visually recognizes the road plan view including the walking trajectories Pi and Pj can easily confirm the route where the jaywalking is likely to occur. Further, the position of the jaywalking-triggering point Q can be easily visually recognized.

In FIG. 4, “G” is a line segment representing an “installation point” of a structure (for example, a sidewalk fence, a guardrail, or the like) for controlling a jaywalking by the pedestrian 6. The control unit 51 of the management device 5 draws an installation point G for recommending the installation of the structure at a position separated from the boundary line R toward the sidewalk by a predetermined length (for example, a 30 cm), for example. By drawing the installation point G, users can easily visually recognize the position of the installation point G for the structures that controls the jaywalking.

### Other Modifications

The above-described embodiments are illustrative in all aspects and are not restrictive. The scope of the present invention includes all modifications within a range equivalent to the configuration described in the claims. For example, in the analysis process (FIG. 2) described above, the detection data may be converted into the general-purpose coordinate system, and the tracking process (step ST11) and the subsequent processes may be executed. In this case, since the detection data is expressed by the general-purpose coordinate values, the coordinate transformation (step ST13) is not necessary.

In the above-described embodiment, the tracking process (step ST11 in FIG. 2) may be executed by the roadside communication device 2. That is, the roadside communication device 2 may generate the local internal trajectory Pa, which is time-series data of the pedestrian position in the detection area A, and transmit the local internal trajectory Pa to the management device 5. In this case, the control unit 51 of the management device 5 may record the local internal trajectory Pa received from the roadside communication device 2 in the sensor database 54, and execute the motion estimation and the processing after the motion estimation (step ST12 in FIG. 2) using the recorded local internal trajectory Pa as input information.

In the above-described embodiments, the case where the moving object that makes a jaywalking is “pedestrian” is illustrated, but the following moving objects are also assumed as moving objects that may jaywalk the roadway.
1) Electric or non-electric wheelchair
2) Electric or non-electric bicycle
3) Electric or non-electric skateboard
4) Electric or non-electric kick board

Thus, in the above-described embodiments, the analysis target of the analysis process (FIG. 2) may be also extended to the moving object not only the pedestrian. In this case, in the analysis process described above, the pedestrian may be read as “moving object”, and the walking trajectory may be read as “movement trajectory”. Further, in a case where the image of the movement trajectory is output, when the trajectory is displayed in different manners (for example, color, line thicknesses, blinking, or flowing dashed line) for each type of moving objects, the user can easily identify which moving object is easy to make a jaywalking.

### REFERENCE SIGNS LIST

1 detector (roadside sensor, pedestrian sensor)
2 roadside communication device
3 vehicle
4 in-vehicle communication device
5 management device
6 pedestrian
7 pedestrian light
8 pole
9 pole arm
10 wireless base station
11 public communication network
51 control unit
52 storage unit
53 communication unit
54 sensor database
55 computer program
56 operation unit
57 display unit
100 safe driving assistance system
J intersection
C crosswalk
A detection area
Pa local internal trajectory
Pb local external trajectory
PA general internal trajectory
PB general external trajectory
Pi walking trajectory including external trajectory (first trajectory)
Pj walking trajectory not including external trajectory (second trajectory)
Q jaywalking-triggering point
G installation point

1. A walking trajectory analysis apparatus for analyzing a walking trajectory of a pedestrian, the walking trajectory analysis apparatus comprising:
storage circuitry configured to store, as internal trajectories, time-series data of a pedestrian position based on detection data from a detector with a detection area including a crosswalk; and
control circuitry configured to calculate an external trajectory based on an internal trajectory determined to be jaywalking among the internal trajectories stored in the storage circuitry, the external trajectory being the walking trajectory outside the detection area, the jaywalking involving crossing a roadway area excluding the crosswalk.

2. The walking trajectory analysis apparatus according to claim 1, wherein
the control circuitry is
capable of executing image output to draw the walking trajectory on a road map including the crosswalk, and
a target to be drawn through the image output includes
a first trajectory, the first trajectory being the walking trajectory including the external trajectory.

3. The walking trajectory analysis apparatus according to claim 2, wherein the target to be drawn through the image output further includes
a second trajectory, the second trajectory being the walking trajectory not including the external trajectory, and
the first trajectory and the second trajectory are
displayed in different manners that are distinguishable by a user.

4. The walking trajectory analysis apparatus according to claim 2, wherein
the control circuitry is configured to determine a jaywalking-triggering point at which the pedestrian who performs the jaywalking starts to enter a roadway, and
the target to be drawn through the image output further includes the jaywalking-triggering point.

5. The walking trajectory analysis apparatus according to claim 4, wherein
the target to be drawn through the image output further includes
an installation point of a structure configured to control the jaywalking, the installation point being identified based on the jaywalking-triggering point.

6. The walking trajectory analysis apparatus according to claim 1, wherein
the control circuitry is configured to
determine the jaywalking, based on a time during which the pedestrian is continuously present in the roadway area excluding the crosswalk.

7. A walking trajectory analysis method for analyzing a walking trajectory of a pedestrian by a computer, the walking trajectory analysis method comprising:
storing, as internal trajectories, time-series data of a pedestrian position based on detection data from a detector with a detection area including a crosswalk; and
calculating an external trajectory based on an internal trajectory determined to be jaywalking among the stored internal trajectories, the external trajectory being the walking trajectory outside the detection area, the jaywalking involving crossing a roadway area excluding the crosswalk.

8. A non-transitory computer-readable storage medium storing a computer program for causing a computer to function as an apparatus for analyzing a walking trajectory of a pedestrian, the computer program causing the computer to:
store, as internal trajectories, time-series data of a pedestrian position based on detection data from a detector with a detection area including a crosswalk; and
calculate an external trajectory based on an internal trajectory determined to be jaywalking among the stored internal trajectories, the external trajectory being the walking trajectory outside the detection area, the jaywalking involving crossing a roadway area excluding the crosswalk.

9. A movement trajectory analysis apparatus for analyzing a movement trajectory of a moving object, the movement trajectory analysis apparatus comprising:
storage circuitry configured to store, as internal trajectories, time-series data of a moving-object position based on detection data from a detector with a detection area including a crosswalk; and
control circuitry configured to calculate an external trajectory based on an internal trajectory determined to be jaywalking among the internal trajectories stored in the storage circuitry, the external trajectory being the movement trajectory outside the detection area, the jaywalking involving crossing a roadway area excluding the crosswalk.
